(19) United States
(12) Patent Application Publication
(10) Pub. No.: US 2021/0001520 A1
(43) Pub. Date: Jan. 7, 2021

(54) METHODS AND APPARATUS FOR MICROWAVE PROCESSING OF POLYMER MATERIALS

(71) Applicant: APPLIED MATERIALS, INC., Santa Clara, CA (US)

(72) Inventors: Tuck Foong KOH, Singapore (SG); Chien-Kang HSIUNG, Taipei (TW); Yueh Sheng OW, Singapore (SG); Felix DENG, Singapore (SG); Yue CUI, Singapore (SG); Nuno Yen-Chu CHEN, Singapore (SG); Ananthkrishna JUPUDI, Singapore (SG); Clinton GOH, Singapore (SG); Vinodh RAMACHANDRAN, Singapore (SG)

(21) Appl. No.: 16/919,736

(22) Filed: Jul. 2, 2020

Related U.S. Application Data
(60) Provisional application No. 62/871,181, filed on Jul. 7, 2019.

(51) Int. Cl. B29C 35/08; H05B 6/80; H05B 6/70; H05B 6/68

(52) U.S. Cl. CPC B29C 35/0805; H05B 6/80; B29K 2079/08; H05B 6/68; H05B 6/705

(57) ABSTRACT

Methods and apparatus for curing a substrate or polymer using variable microwave frequency are provided herein. In some embodiments, a method of curing a substrate or polymer using variable microwave frequency includes: contacting a substrate or polymer with a plurality of predetermined discontinuous microwave energy bandwidths or a plurality of predetermined discontinuous microwave energy frequencies to cure the substrate or polymer.

### CROSS-REFERENCE TO RELATED APPLICATIONS

This application claims benefit of U.S. provisional patent application Ser. No. 62/871,181, filed Jul. 7, 2019 which is herein incorporated by reference in its entirety.

### FIELD

Embodiments of the present disclosure generally relate to apparatus and methods for materials processing using microwave energy. More particularly, the present disclosure relates to curing substrates such as polymers using microwave energy.

### BACKGROUND

Layers of various conductive and non-conductive polymeric materials are applied to semiconductor wafers during various stages of production. For example, organic materials (e.g., such as polyimide (PI), poly(p-phenylene benzobisoxazole (PBO), phenolic resin, epoxy, or benzocyclobutene (BCB), etc.) or inorganic materials (e.g., such as silicon, silicon oxide, oxide, oxynitride, nitride, or carbide, etc.) are frequently used in semiconductor manufacturing for forming dielectric layers of interconnects (e.g., packaging's Redistribution Layer process (RDLs) or Back-end of line (BEOL)). The back end of line (BEOL) is the second portion of IC fabrication where the individual devices get interconnected with wiring on the substrate.

Typically, the substrates such as polymers formed, including dielectric layers/films, have fixed electrical, thermo-mechanical, and chemical properties. Furthermore, the substrates such as polymers above typically require longer times and higher temperatures to cure when conventional heating techniques are used leading to throughput issues as well as creating defects on the substrates. For example, when polyimide is cured using conventional heating techniques, the outer surface of the polymer typically cures faster than the center portions resulting in various physical defects, such as the formation of voids, and can result in inferior mechanical properties such as reduced modulus, enhanced swelling, solvent uptake, and coefficient of thermal expansion. Furthermore, the higher temperatures used in conventional curing techniques creates a lot of warpage due to differences in thermal expansion of the materials present during in packaging RDL process.

Accordingly, the inventors have developed improved methods of forming substrates such as polymers that can be cured faster and at lower temperatures.

### SUMMARY

Methods of curing a substrate or polymer using variable microwave frequency are provided herein. In some embodiments, a method of curing a substrate or polymer using variable microwave frequency includes: contacting a substrate or polymer with a plurality of predetermined discontinuous microwave energy bandwidths or a plurality of predetermined discontinuous microwave energy frequencies to cure the substrate or polymer.

In some embodiments, a substrate processing system includes: a variable frequency microwave chamber configured for contacting a polymer with a plurality of predetermined discontinuous microwave energy bandwidths or discontinuous microwave frequencies to cure the polymer.

In some embodiments, a computer readable medium, having instructions stored thereon which, when executed, cause a variable frequency microwave process chamber to perform methods as described in any of the embodiments disclosed herein. In some embodiments, the method includes: contacting a substrate or polymer with a plurality of predetermined discontinuous microwave energy bandwidths or a plurality of predetermined discontinuous microwave energy frequencies to cure the substrate or polymer.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart for a method of curing in accordance with some embodiments of the present disclosure.

FIG. 2 depicts a schematic side view of a process chamber for a microwave curing process in accordance with some embodiments of the present disclosure.

FIG. 3 depicts a flow chart for a method of curing a substrate or polymer in accordance with some embodiments of the present disclosure.

FIG. 4 depicts a top plan view of a processing tool including the apparatus of FIG. 2 in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure including apparatus and methods of curing substrate or polymer such as a polymer layer on a substrate using variable microwave frequency are provided herein. For example, methods of the present disclosure include contacting a substrate or polymer with a plurality of predetermined discontinuous microwave energy bandwidths or a plurality of predetermined discontinuous microwave energy frequencies to cure the substrate or polymer. Embodiments of the present disclosure advantageously allow flexible semiconductor material forming process during manufacturing using Variable Frequency Microwave (VFM) technology to (1) cure material such as a substrate, polymer, or polymer layer at lower temperature thus reducing difference in thermal expansion that results in lower warpage in packaging RDL process, and/or (2) modify a substrate, polymer, or polymer layer for better electrical (e.g., lower parasitic capacitance, higher breakdown voltage) and thermal-mechanical (e.g., higher glass transition temperature or higher elongation that exhibits stronger mechanical stress, good thermal conductivity, etc.) properties.

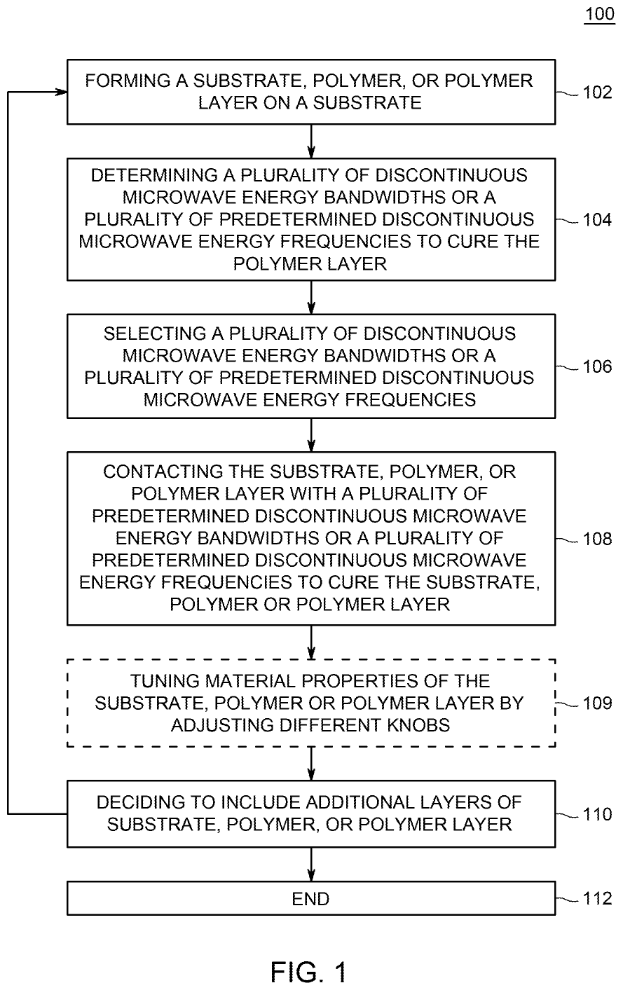

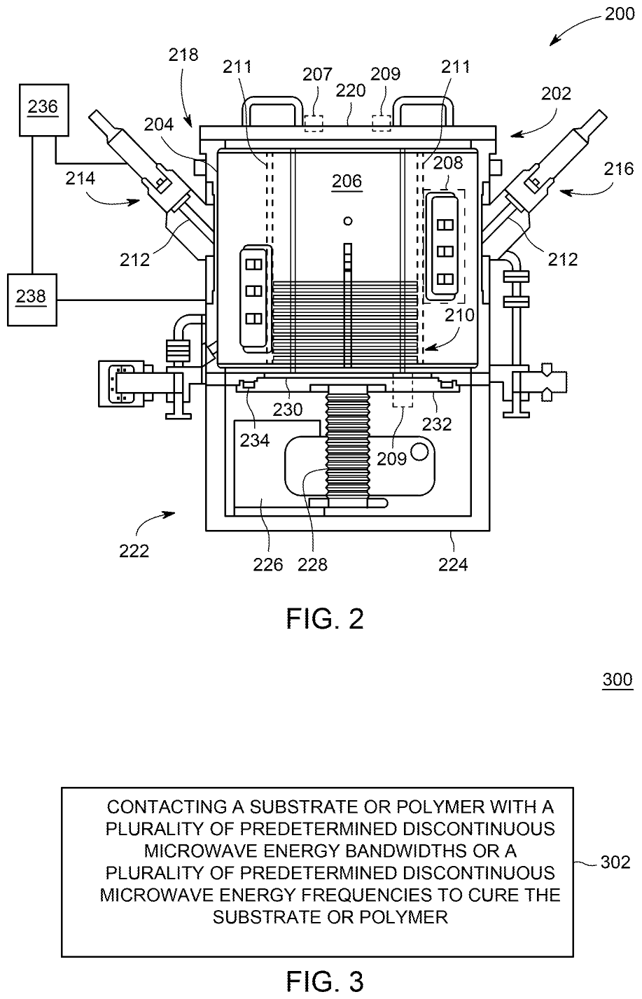

FIG. 1 is a flow diagram of a method 100 of curing a material such as a substrate, polymer, or polymer layer on a semiconductor substrate in accordance with some embodiments of the present disclosure. A semiconductor substrate or a polymer such as a polymer layer disposed on a substrate is placed into a suitable microwave processing chamber such as discussed below with respect to FIG. 2.

In some embodiments, suitable substrates for curing as described herein include a material such as crystalline silicon (e.g., Si<100> or Si<111>), silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, and combinations thereof. In some embodiments, inorganic substrates are suitable for curing in accordance with the present disclosure. Non-limiting examples inorganic substrates include one or more of an inorganic dielectric material formed of one of silicon, silicon oxide, oxide, oxynitride, nitride, or carbide.

In embodiments, the substrate may have various dimensions, such as 200 mm, 300 mm, 450 mm or other diameters for round substrates. The substrate may also be any polygonal, square, rectangular, curved or otherwise non-circular workpiece, such as a polygonal glass substrate used in the fabrication of flat panel displays. Unless otherwise noted, implementations and examples described herein are conducted on substrates such as a substrate with a 200 mm diameter, a 300 mm diameter, or a 450 mm diameter substrate.

In some embodiments, substrates for curing herein include one or more low-k dielectric layers alone or deposited atop a substrate by any suitable atomic layer deposition process or a chemical vapor deposition process to a desired thickness. In embodiments, the low-k dielectric layer is generally formed from a material having a low-k value suitable for insulating material. Non-limiting materials suitable as low-k dielectric material may comprise a silicon containing material, for example, such as silicon oxide (SiO₂), silicon nitride, or silicon oxynitride (SiON), or combinations thereof. In some embodiments, the low-k dielectric material may have a low-k value of less than about 3.9 (for example, about 2.5 to about 3.5). In embodiments, a low-k dielectric layer comprises material including one or more of polyimides, polytetrafluoroethylenes, parylenes, polysilsesquioxanes, fluorinated poly(aryl ethers), fluorinated amorphous carbon, silicon oxycarbides, and silicon carbides. In some embodiments, a substrate such as a low-k dielectric layer comprises silicon oxycarbides, including, for example, silicon oxycarbides including various silicon, carbon, oxygen, and hydrogen containing materials.

In some embodiments, polymer or polymer layers are suitable for curing in accordance with the present disclosure. Non-limiting examples of polymer or polymers layers include one or more of an organic dielectric material formed from one of polyimide (PI), poly(p-phenylene benzobisoxazole (PBO), phenolic resin, epoxy, or benzocyclobutene (BCB).

In some embodiments, the method 100 is performed at atmosphere such as 1 ATM or at vacuum (e.g., about 50 to about 1e−6 Torr, or below). The inventors have observed that in some embodiments, curing a polymer in atmosphere allows more microwave power, of selected effective frequencies to be delivered into a process chamber and polymer or polymer layer. However, in some embodiments, performing the method 100 at vacuum helps to drive out solvents, additives, and reaction byproducts that form during the curing process. Conventional non-microwave curing occurs at about 1 atmosphere, or sub-atmosphere at the lowest and thus uses high temperature to drive out solvents, additives, or reaction byproducts.

In some embodiments, the method 100 begins at 102, where a substrate such as a polymer or polymer layer on a substrate in need of curing is formed of materials such as those described above. In some embodiments, a substrate, polymer or polymer layer of about 1.0 micron to about 1000 microns thick is deposited. In some embodiments, the polymer or polymer layer may be a dielectric material such as an organic based dielectric material. For example, one or more of polyimide (PI), poly(p-phenylene benzobisoxazole (PBO), phenolic resin, epoxy, or benzocyclobutene (BCB). In some embodiments, a substrate formed may be an inorganic dielectric material formed of one of oxide, silicon oxide, silicon, oxynitride, nitride, or carbide, and the like.

In some embodiments, the substrate, polymer, or polymer layer may further comprise at least one microwave tunable material included in the substrate, polymer, or polymer layer, or otherwise added to an organic or inorganic dielectric material, such as a material that is (a) a high polar additive to speed up curing process and reduce the curing temp, (b) a microwave responsive additive with certain desired properties (electrical, mechanical and thermal, chemical, etc.), and/or (c) non-polar materials with certain desired properties. Non-limiting examples of polar additives may include water, ethanol, methanol, isopropanol (IPA), acetic acid, acetone, n-propanol, n-butanol, formic acid, propylene, carbonate, ethyl acetate, dimethyl sulfoxide, acetonitrile (MECN), dimethylformamide, tetrahydrofuran, and/or dichloromethane. In some embodiments, the non-polar additives may include pentane, cyclopentane, hexane, cyclohexane, benzene, toluene, dioxane, chloroform, and/or diethyl ether. In contrast to non-polar additives, polar additives have significantly higher dielectric constants and dipole moments. Like the water molecules, in presence of microwave energy these polar molecules will be set into rotational movement (possible in available space). Anywhere the vapors of these solvents can deposit, even deep into the pores of the porous dielectric film, microwave energy has the capability to agitate these molecules and stir up the reaction. In embodiments, process conditions stay below the boiling point of the solvent or reagent to allow some additional rotational movement within the pores before going to higher process temperature.

The range of frequencies within the electromagnetic spectrum from which microwave frequencies suitable for curing in accordance with the present disclosure may be chosen is a range from 300 GHz to 300 MHz, or in some embodiments, in a range of 1 GHz to 100 GHz. In some embodiments, substrates, polymers, or polymers layers to be treated in accordance with the present disclosure are exposed to microwave energy including two or more bandwidths or ranges of frequencies suitable for curing the substrates, polymers, or polymers layers that show increased reactivity or absorption of the two or more bandwidths. The bandwidths and specific frequencies therein may be preselected for curing. At 104, a determination is made to identify a plurality of discontinuous microwave energy bandwidths or a plurality of predetermined discontinuous microwave energy frequencies to cure the polymer layer. In embodiments, absorptions bands of materials such as substrate, polymers or polymer layers are investigated to determine which microwave energy bandwidths or microwave energy frequencies will promote efficient curing, and exclude microwave energy bandwidths or microwave energy frequencies that are less efficient or fail to absorb into the substrate, polymer, or polymer layer of interest. In some embodiments, absorption bands of substrate, polymer, or polymer layers are evaluated with methods known in the art of determining microwave absorption properties of a material such as those described in Dielectric Characteristics and Microwave Absorption of Graphene Composite Materials, Materials 9,825 (2016) to Rubrice et al. In embodiments, measuring microwave reflection and absorption in a substrate, polymer, or polymer layer provides details to determine, or predetermine a plurality of discontinuous microwave energy bandwidths suitable to cure the polymer layer. In embodiments, measuring microwave reflection and absorption in a substrate, polymer, or polymer layer provides details to determine or predetermine a plurality of discontinuous microwave energy frequencies suitable to cure the polymer layer. In accordance with the present disclosure two or more or a plurality of discontinuous microwave energy bandwidths refers to bandwidths having one or more gaps between bandwidths. For example, discontinuous microwave energy bandwidths may have a first bandwidth at a low frequency range and a second bandwidth at a second frequency range, wherein the first bandwidth and second bandwidth do not overlap and do not share a frequency range limit. Non-limiting examples of discontinuous microwave energy bandwidths include a first bandwidth at 5.25 GHz to about 5.85 GHz, and a second bandwidth at 5.95 GHz and 6.22 GHz, or, in embodiments, a first bandwidth at 5.25 GHz to about 5.85 GHz, a second bandwidth at 5.95 GHz and 6.22 GHz, and a third bandwidth at 6.4 GHz to 6.88 GHz. In each of these examples, microwave energy at frequencies between the recited bandwidths or frequency ranges is not provided during a cure in accordance with the present disclosure. In some embodiments, a plurality of predetermined discontinuous microwave energy bandwidths include 2 to 20 predetermined discontinuous microwave energy bandwidths.

In accordance with the present disclosure two or more or a plurality of discontinuous microwave energy frequencies refers to frequencies having one or more gaps between frequencies. For example, discontinuous microwave energy frequencies may have a first frequency at a low frequency than a second frequency, wherein the first frequency and second frequency do not overlap and are not adjacent one another on the electromagnetic spectrum. Non-limiting examples of discontinuous microwave energy frequencies include a first frequency at 5.25 GHz, and a second frequency at 5.95 GHz, or, in embodiments, a first frequency at 5.27 GHz, a second frequency at 5.97 GHz and a third frequency at 6.4 GHz. In each of these examples, microwave energy at frequencies between the recited frequencies are not provided during a cure in accordance with the present disclosure. In some embodiments, a plurality of predetermined discontinuous microwave energy frequencies include 2 to 20 predetermined discontinuous microwave energy frequencies.

Based on material absorption properties, one of ordinary skill in the art may correlate the absorption bands with a wide frequency range microwave supply, and determine or select the incident discontinuous microwave energy frequencies and/or discontinuous microwave energy bandwidths suitable for use in accordance with the present disclosure. For example, at 106, the process sequence includes selecting a plurality of discontinuous microwave energy bandwidths or a plurality of predetermined discontinuous microwave energy frequencies suitable for curing in accordance with the present disclosure. In embodiments, selected discontinuous microwave energy bandwidths or frequencies include bandwidth or frequencies that are highly absorbed, and exclude bandwidths or frequencies that are not well absorbed by the substrate or polymer of interest.

At 108, the substrate, polymer, or polymer layer is contacted with a plurality of predetermined discontinuous microwave energy bandwidths or a plurality of predetermined discontinuous microwave energy frequencies to cure the substrate, polymer or polymer layer. In some embodiments, substrate, polymer or polymer layer is contacted with a plurality of predetermined discontinuous microwave energy bandwidths including 2 to 20 predetermined discontinuous microwave energy bandwidths. In some embodiments, substrate, polymer or polymer layer is contacted with a plurality of predetermined discontinuous microwave energy frequencies including 2 to 20 predetermined discontinuous microwave energy frequencies. In some embodiments, contacting the substrate, polymer, or polymer layer with the plurality of predetermined discontinuous microwave energy bandwidths to cure the polymer layer further includes hopping among the plurality of predetermined discontinuous microwave energy bandwidths or plurality of predetermined discontinuous microwave energy frequencies in a predetermined order. For example, curing may be performed by hopping between 2 to 20 predetermined discontinuous microwave energy bandwidths or plurality of predetermined discontinuous microwave energy frequencies in a predetermined order, without providing microwave energy in the gaps between the predetermined discontinuous microwave energy bandwidths or plurality of predetermined discontinuous microwave energy frequencies.

In some embodiments, the substrate, polymer or polymer layer is cured at a temperature below 200 degrees Celsius, such as between 100 degrees Celsius and 200 degrees Celsius. In some embodiments, the substrate, polymer, or polymer layer is cured in 1 to 180 minutes such as 1 to 60 minutes. In embodiments, contact with a plurality of predetermined discontinuous microwave energy bandwidths or a plurality of predetermined discontinuous microwave energy frequencies will heat the substrate (e.g., a semiconductor substrate), polymer, or polymer layer to heat the substrate, polymer, or polymer layer to a first temperature. In some embodiments, the substrate, polymer, or polymer layer is heated from about room temperature (e.g., about 25 degrees Celsius) to a first temperature of about 100 to about 200 degrees Celsius (i.e., a soak temperature). In some embodiments, the substrate, polymer, or polymer layer is heated to remove any residual solvents in the polymer layer. In some embodiments, the substrate, polymer, or polymer layer is heated from room temperature to the first temperature at a first rate of about 0.01 degrees Celsius to about 4 degrees Celsius per second, such as about 2 degrees Celsius per second. In some embodiments, the substrate, polymer, or polymer layer is maintained at the first temperature for a first period of time sufficient to remove any residual solvents. In some embodiments, the first period of time is about 1 minutes to about 180 minutes such as 1 to 60 minutes. Furthermore, in some embodiments, the substrate, polymer, or polymer layer is maintained at the first temperature for the first period of time selected to tune, or control, material properties of the substrate, polymer, or polymer layer.

In some embodiments, the temperature of the substrate, polymer, or polymer layer is controlled by the amount of microwave energy applied as a plurality of predetermined discontinuous microwave energy bandwidths or as a plurality of predetermined discontinuous microwave energy frequencies to the substrate, polymer, or polymer layer. In embodiments, the preselection of a plurality of predetermined discontinuous microwave energy bandwidths or a plurality of predetermined discontinuous microwave energy frequencies efficiently applies microwave energy to the polymer, polymer layer and/or the semiconductor substrate.

In some embodiments, the substrate, polymer, or polymer layer is subjected to microwave energy preselected from a source with microwave frequencies ranging from about 300 GHz to 300 MHz. For example, the plurality of predetermined discontinuous microwave energy bandwidths or the plurality of predetermined discontinuous microwave energy frequencies are provided at microwave frequencies ranging from 300 GHz to 300 MHz. In some embodiments, the substrate, polymer, or polymer layer is subjected to microwave energy wherein the plurality of predetermined discontinuous microwave energy bandwidths or the plurality of predetermined discontinuous microwave energy frequencies are from a broad C-band source with microwave frequencies ranging from about 5.85 GHz to about 6.65 GHz. In some embodiments, the sweep rate is about 25.0 microseconds per frequency to 1000 microseconds per frequency across 4096 frequencies in the C-band.

In some embodiments, at 109, the material properties of the substrate, polymer, or polymer layer may optionally be further tuned by adjust different tuning knobs. Example knobs/controls that may be adjusted for tuning purposes may include controls that control the following chamber processing parameters: frequency, power, temperature, pressure, waveguide configuration, chamber configuration, assistive hardware to tune the microwave distribution in chamber, and the like. In some embodiments, the variable microwave frequency, or other chamber processing parameters, may be tuned to selectively heat up certain component(s) of substrate (i.e., a particular layer, or a particular structure formed on the substrate or polymer layers, etc.) or the process chamber itself. In some embodiments, variable frequency microwave as described herein is suitable for activating chemical functional groups, or preselected chemical functional groups or nanoparticles in a substrate or polymer. In some embodiments, variable frequency microwave as described herein is suitable for activating chemical functional groups, or preselected chemical functional groups or nanoparticles in epoxy. In embodiments, a microwave may include knobs that change the bandwidths or frequency of microwave energy in a predetermined discontinuous pattern.

At 110, if additional polymer layers are to be formed, the method returns to 102 and repeats again until all layers are formed and tuned to the desired properties to form a semiconductor structure. At 110, if no additional polymer layers are to be formed, the method ends at 112.

The method 100 advantageously creates a semiconductor structures that have cured substrate, polymer, or polymer layers and may have electrical material properties that can be tuned (dielectric constant, loss factor, loss tangent, breakdown voltage, etc.), mechanical material properties that can be tuned (e.g., elongation, modulus, tensile strength, etc.), thermal material properties that can be tuned (CTE, thermal conductivity, 5% weight loss, thermal stability, etc.), and chemical material properties that can be tuned (resistance to various chemistries).

In some embodiments, the methods described above can be used to form a plurality of polymer layers on a substrate using variable microwave frequency as described herein wherein each of the plurality of polymer layers is cured and may include at least one base dielectric material and at least one microwave tunable material, and wherein a different variable frequency microwave energy is applied to each of the plurality of polymer layers such that each of the each of the plurality of polymer layers has been tuned to exhibit different material properties from an adjacent layer.

FIG. 2 depicts a suitable microwave processing chamber 200 for performing the method 100 described above. For example, the microwave processing chamber 200 may be configured for contacting a substrate, polymer, or polymer layer with a plurality of discontinuous microwave energy bandwidths or a plurality of discontinuous microwave energy frequencies sufficient to cure the substrate, polymer, or polymer layer. In some embodiments, the microwave processing chamber 200 includes a cylindrical, or in some embodiments an octagonal body such as body 202. In some embodiments, body 202 has a thickness sufficient for use as a microwave chamber. In some embodiments, body 202 comprises a cylindrical or octagonal cavity such as cavity 204 having a first volume 206. One or more substrates 210 polymers, or polymer layers, for example semiconductor wafers or other substrates having materials to be microwave cured may be disposed within the cavity 204 during curing operations. A top 218 of the body 202 has a lid 220 to seal the first volume 206. In some embodiments, top 218 does not include a lid, and a door may be provided to metal mesh to isolate microwave energy. In some embodiments a waveguide 209 may enter chamber from lid 220 or bottom. In some embodiments, a liner 211 may be included to surround the first volume 206. In embodiments, the liner is cylindrical or octagonal, and configured to attenuate or modulate microwave energy in the first volume 206. In embodiments, liner 211 is configured to increase thermal conditions of the substrates 210, polymers, or polymer layers.

In some embodiments, body 202 is suitable for receiving variable frequency microwave energy including a plurality of discontinuous microwave energy bandwidths or a plurality of discontinuous microwave energy frequencies sufficient to cure the substrates or polymers in accordance with the present disclosure. The body 202 further comprises a plurality of openings 208 or top openings 207 fluidly coupled to the first volume 206. In embodiments, the plurality of openings 208 or top opening 207 may be different hole sizes to alter the gas flow, and may extend through the lid and or body 202. In some embodiments, a plurality of openings 208 facilitates delivery of the microwave energy to the first volume 206. The plurality of openings 208 are coupled to a suitable variable frequency microwave source 238, such as a microwave source configured to provide a plurality of predetermined discontinuous microwave energy bandwidths or a plurality of predetermined discontinuous microwave energy frequencies to sufficient to cure a substrate, polymer, or polymer layer in accordance with the present disclosure. In some embodiments, each opening 208 may be rectangular. In some embodiments, each opening 208 may include angled sidewalls that enlarge the opening on a side of the opening facing the first volume 206. In some embodiments, the openings 208 are staggered, or spaced apart, along the body 202. In some embodiments, the body 202 comprises four openings 208, wherein two of the four openings 208 are disposed along the body 202 opposite to each other and the other two openings 208 are disposed along the body 202 opposite to each other but not opposite to the first two openings 208. In some embodiments, each opening 208 is a singular opening along the body 202. In some embodiment, each opening 208 comprises multiple openings along the body 202.

In some embodiments, the body 202 comprises one or more ports 212 fluidly coupled to the first volume 206. One or more temperature sensors 214, 216 are disposed within the ports 212 to measure a temperature of the one or more semiconductor substrates within the first volume 206. The temperature sensors 214, 216 are coupled to a PID controller 236, which is coupled to the variable frequency microwave source 238 to control the amount of microwave power supplied to the microwave processing chamber 200. In embodiments, temperature control may be achieved with IR sensors, thermocouples/optic fibers by attachment to wafer supports or other components in the process chamber. In some embodiments, an exhaust port (not shown) may be coupled to the body 202 and fluidly coupled to the first volume 206 to create a vacuum within the first volume 206 suitable for performing method 100.

In some embodiments, the microwave processing chamber 200 further includes a substrate transfer apparatus 222 having a lower chamber 224. The lower chamber 224 is disposed below the body 202 and is coupled to the body 202. The lower chamber 224 comprises a second volume 226 holding one or more substrates 210 (such as semiconductor substrates, polymer or polymer layers). The second volume 226 is fluidly coupled to the first volume 206. In some embodiments, the one or more substrates 210 such as polymers or polymer layers are aligned parallel to each other in a stacked configuration.

A lift mechanism 228 is provided to lift the one or more substrates 210 from the lower chamber 224 into the first volume 206 of the cavity 204. The lift mechanism 228 may be any suitable lift mechanism, such as an actuator, motor, or the like. In some embodiments, the lift mechanism 228 is coupled to a substrate support 230 that may be disposed in the lower chamber 224 or moved into the first volume 206 of the cavity 204.

Once the one or more substrates 210 are raised into the first volume 206 of the cavity 204, a lower plate 232 coupled to the substrate support 230 seals a second volume 226 of the lower chamber 224 from the first volume 206 of the cavity 204 to prevent escape of microwaves and maintain a predetermined pressure in the first volume 206. The lower plate 232 butts up against, or mates with, an adapter 234 such that there is no gap, or a minimal gap, between the lower plate 232 and the adapter 234, thus sealing the first volume 206. The adapter 234 is coupled to an inner surface of the lower chamber 224.

FIG. 3 depicts a flow chart for a method of curing a substrate, polymer, or polymer layer in accordance with some embodiments of the present disclosure. In some embodiments, a method 300 of curing a substrate, polymer, or polymer layer on a substrate using variable microwave frequency, may optionally include forming a polymer layer on a substrate. In embodiments, method 300 begins at 302 with contacting a substrate or polymer with a plurality of predetermined discontinuous microwave energy bandwidths or a plurality of predetermined discontinuous microwave energy frequencies to cure the substrate or polymer. In some embodiments, a substrate or polymer such as a polymer layer is cured at a temperature below 500 degrees Celsius or below 200 degrees Celsius such as between 50 and 200 degrees Celsius. In some embodiments, the substrate or polymer such as a polymer layer is cured in 1 to 60 minutes. In some embodiments, the plurality of predetermined discontinuous microwave energy bandwidths includes 2 to 20, or 5 to 10 predetermined discontinuous microwave energy bandwidths. In some embodiments, the plurality of predetermined discontinuous microwave energy frequencies comprises 2 to 20, or 5 to 10 predetermined discontinuous microwave energy frequencies. In some embodiments, contacting the substrate or polymer such as a polymer layer with the plurality of predetermined discontinuous microwave energy bandwidths to cure the substrate or polymer further comprises hopping among a plurality of predetermined discontinuous microwave energy bandwidths in a predetermined order. In some embodiments, contacting a polymer layer with a plurality of predetermined discontinuous microwave energy frequencies to cure the polymer layer further includes hopping among the plurality of predetermined discontinuous microwave energy frequencies in a predetermined order. In some embodiments, contacting the polymer layer with the plurality of predetermined discontinuous microwave energy bandwidths to cure the polymer layer further includes hopping among the plurality of predetermined discontinuous microwave energy bandwidths in a predetermined order and predetermined duration. In some embodiments, contacting the polymer layer with the plurality of predetermined discontinuous microwave energy frequencies to cure the polymer layer further includes hopping among the plurality of predetermined discontinuous microwave energy frequencies in a predetermined order and predetermined duration. In some embodiments, at least one material property of the polymer layer is tuned by adjusting one or more tuning knobs. In embodiments, the microwave configured to perform the methods of the present disclosure includes tuning knobs configured to adjust at least one of frequency, power, temperature, pressure, waveguide configuration, chamber configuration, or in-chamber microwave distribution. In some embodiments, the plurality of predetermined discontinuous microwave energy bandwidths or the plurality of predetermined discontinuous microwave energy frequencies are provided at microwave frequencies ranging from 300 GHz to 300 MHz. In some embodiments, contacting the polymer layer with the plurality of predetermined discontinuous microwave energy bandwidths or the plurality of predetermined discontinuous microwave energy frequencies to cure the polymer layer is performed at about 100 degrees to about 200 degrees Celsius. In some embodiments, the plurality of predetermined discontinuous microwave energy bandwidths or the plurality of predetermined discontinuous microwave energy frequencies is provided at a sweep rate of about 25.0 microseconds per frequency to 1000 microseconds per frequency. In some embodiments, curing is performed within a microwave processing chamber under vacuum. In some embodiments, the polymer layer is one of an organic dielectric material formed from one of polyimide (PI), poly(p-phenylene benzobisoxazole (PBO), phenolic resin, epoxy, or benzocyclobutene (BCB), or an inorganic dielectric material formed of one of oxide, oxynitride, nitride, or carbide.

In some embodiments, the methods further include determining a plurality of discontinuous microwave energy bandwidths or a plurality of predetermined discontinuous microwave energy frequencies to cure the polymer layer. In some embodiments, the methods further include selecting a plurality of discontinuous microwave energy bandwidths or a plurality of predetermined discontinuous microwave energy frequencies.

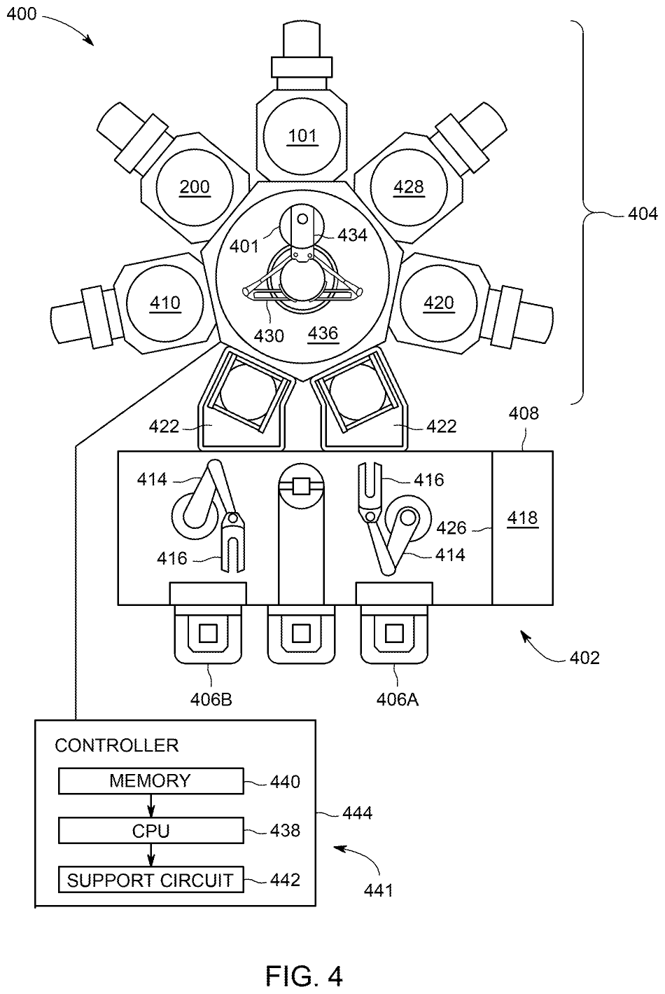

FIG. 4 is a schematic, top plan view of an exemplary integrated system 400 that includes one or more of the deposition processing chambers 101 and/or microwave processing chamber 200 configured for use in accordance with the present disclosure as illustrated in FIG. 2. In some embodiments, the integrated system 400 may be a CENTURA® integrated processing system, commercially available from Applied Materials, Inc., located in Santa Clara, Calif. Other processing systems (including those from other manufacturers) may be adapted to benefit from the disclosure.

In some embodiments, the integrated system 400 includes a vacuum-tight processing platform such as processing platform 404, a factory interface 402, and a system controller 444. The processing platform 404 includes at least one deposition processing chamber 101, at least one microwave processing chamber 200, such as microwave processing chamber 200 depicted from FIG. 2, and optionally a plurality of processing chambers 428, 420, 410 and at least one load lock chamber 422 that is coupled to a vacuum substrate transfer chamber such as transfer chamber 436. Two load lock chambers 422 are shown in FIG. 4. The factory interface 402 is coupled to the transfer chamber 436 by the load lock chambers 422.

In one embodiment, the factory interface 402 comprises at least one docking station 408 and at least one factory interface robot 414 to facilitate transfer of substrates. The docking station 408 is configured to accept one or more front opening unified pod (FOUP). Two FOUPS 406A-B are shown in the embodiment of FIG. 4. The factory interface robot 414, having a blade 416 disposed on one end of the factory interface robot 414, is configured to transfer the substrate from the factory interface 402 to the processing platform 404 for processing through the load lock chambers 422. Optionally, one or more processing chambers 410, 420, 428, deposition processing chamber 101, microwave processing chamber 200 may be connected to a terminal 426 of the factory interface 402 to facilitate processing of the substrate from the FOUPS 406A-B.

Each of the load lock chambers 422 have a first port coupled to the factory interface 402 and a second port coupled to the transfer chamber 436. The load lock chambers 422 are coupled to a pressure control system (not shown) which pumps down and vents the load lock chambers 422 to facilitate passing the substrate between the vacuum environment of the transfer chamber 436 and the substantially ambient (e.g., atmospheric) environment of the factory interface 402.

The transfer chamber 436 has a vacuum robot 430 disposed therein. The vacuum robot 430 has a blade 434 capable of transferring substrates 401 among the load lock chambers 422, the deposition processing chamber 101, microwave processing chamber 200, and the processing chambers 410, 420, and 428.

In some embodiments of the integrated system 400, the integrated system 400 may include a deposition processing chamber 101, and other processing chambers 410, 420, 428, microwave processing chamber 200. In some embodiments, processing chambers 410, 420, 428 may be a deposition chamber, etch chamber, thermal processing chamber or other similar type of semiconductor processing chamber.

The system controller 444 is coupled to the integrated system 400. The system controller 444, which may include the computing device 441 or be included within the computing device 441, controls the operation of the integrated system 400 using a direct control of the processing chambers 410, 420, 428, deposition processing chamber 101, microwave processing chamber 200 of the integrated system 400. Alternatively, the system controller 444 may control the computers (or controllers) associated with the processing chambers 410, 420, 428, deposition processing chamber 101, microwave processing chamber 200 and the integrated system 400. In operation, the system controller 444 also enables data collection and feedback from the respective chambers and the processing chambers such as deposition processing chamber 101, and/or microwave processing chamber 200 to optimize performance of the integrated system 400.

The system controller 444 generally includes a central processing unit (CPU) 438, a memory 440, and support circuits 442. The CPU 438 may be one of any form of a general purpose computer processor that can be used in an industrial setting. The support circuits 442 are conventionally coupled to the CPU 438 and may comprise cache, clock circuits, input/output subsystems, power supplies, and the like. The software routines transform the CPU 438 into a specific purpose computer (system controller) 444. The software routines may also be stored and/or executed by a second controller (not shown) that is located remotely from the integrated system 400.

In some embodiments, the present disclosure includes an integrated system including: a vacuum substrate transfer chamber; a variable frequency microwave chamber configured for contacting a polymer with a plurality of predetermined discontinuous microwave energy bandwidths or discontinuous microwave frequencies to cure the polymer coupled to the vacuum substrate transfer chamber; and an additional chamber coupled to the vacuum substrate transfer chamber, wherein the integrated system is configured to move the polymer from the variable frequency microwave chamber to the additional chamber under vacuum. In some embodiments, the additional chamber is a deposition chamber configured to deposit polymers or polymer layers.

In some embodiments, the present disclosure includes a computer readable medium, having instructions stored thereon which, when executed, cause a variable frequency microwave process chamber to perform a method including forming a polymer layer on a substrate; and contacting the polymer layer with a plurality of predetermined discontinuous microwave energy bandwidths or a plurality of predetermined discontinuous microwave energy frequencies to cure the polymer layer.

In some embodiments, the present disclosure includes a variable frequency microwave process chamber configured to form a polymer layer on a substrate; and contact the polymer layer with a plurality of predetermined discontinuous microwave energy bandwidths or a plurality of predetermined discontinuous microwave energy frequencies to cure the polymer layer.

In some embodiments, the present disclosure relates to a method of curing a substrate, polymer, or polymer layer on a substrate using variable microwave frequency, includes: contacting, e.g., delivering microwave energy to a substrate, polymer, or polymer layer with a plurality of predetermined discontinuous microwave energy bandwidths or a plurality of predetermined discontinuous microwave energy frequencies to cure the polymer layer. In some embodiments, the substrate, polymer, or polymer layer is cured at a temperature below 200 degrees Celsius. In some embodiments, the substrate, polymer, or polymer layer is cured in 1 to 60 minutes. In some embodiments, the plurality of predetermined discontinuous microwave energy bandwidths comprises 2 to 20 predetermined discontinuous microwave energy bandwidths. In some embodiments, the plurality of predetermined discontinuous microwave energy frequencies comprises 2 to 20 predetermined discontinuous microwave energy frequencies. In some embodiments, contacting the substrate, polymer, or polymer layer with the plurality of predetermined discontinuous microwave energy bandwidths to cure the polymer layer further comprises hopping among the plurality of predetermined discontinuous microwave energy bandwidths in a predetermined order. In some embodiments, contacting the substrate, polymer, or polymer layer with the plurality of predetermined discontinuous microwave energy frequencies to cure the polymer layer further comprises hopping among the plurality of predetermined discontinuous microwave energy frequencies in a predetermined order. In some embodiments, contacting the substrate, polymer, or polymer layer with the plurality of predetermined discontinuous microwave energy bandwidths to cure the polymer layer further comprises hopping among the plurality of predetermined discontinuous microwave energy bandwidths in a predetermined order and predetermined duration. In some embodiments, contacting the substrate, polymer, or polymer layer with the plurality of predetermined discontinuous microwave energy frequencies to cure the polymer layer further comprises hopping among the plurality of predetermined discontinuous microwave energy frequencies in a predetermined order and predetermined duration. In some embodiments, at least one material property of the substrate, polymer, or polymer layer is tuned by adjusting one or more tuning knobs. In some embodiments, contacting the substrate, polymer, or polymer layer with the plurality of predetermined discontinuous microwave energy bandwidths or the plurality of predetermined discontinuous microwave energy frequencies to cure the polymer layer is performed at about 100 degrees to about 500 degrees Celsius. In some embodiments, contacting a substrate, polymer, or polymer layer includes delivering microwave energy to the substrate, polymer, or polymer within a microwave processing chamber under vacuum. In some embodiments, the substrate, polymer, or polymer layer is one of an organic dielectric material formed from one of polyimide (PI), poly(p-phenylene benzobisoxazole (PBO), phenolic resin, epoxy, or benzocyclobutene (BCB), or an inorganic dielectric material formed of one of oxide, oxynitride, nitride, or carbide.

In some embodiments, a method of curing a substrate or polymer using variable microwave frequency includes: contacting a substrate or polymer with a plurality of predetermined discontinuous microwave energy bandwidths or a plurality of predetermined discontinuous microwave energy frequencies to cure the substrate or polymer. In some embodiments, the substrate or polymer is cured at a temperature below 200 degrees Celsius. In some embodiments, the substrate or polymer is cured in 1 to 180 minutes. In some embodiments, the plurality of predetermined discontinuous microwave energy bandwidths comprises 2 to 20 predetermined discontinuous microwave energy bandwidths. In some embodiments, the plurality of predetermined discontinuous microwave energy frequencies comprises 2 to 20 predetermined discontinuous microwave energy frequencies. In some embodiments, contacting the substrate or polymer with the plurality of predetermined discontinuous microwave energy bandwidths to cure the substrate or polymer further comprises hopping among the plurality of predetermined discontinuous microwave energy bandwidths in a predetermined order. In some embodiments, contacting the substrate or polymer with the plurality of predetermined discontinuous microwave energy frequencies to cure the substrate or polymer further comprises hopping among the plurality of predetermined discontinuous microwave energy frequencies in a predetermined order. In some embodiments, contacting the substrate or polymer with the plurality of predetermined discontinuous microwave energy bandwidths to cure the substrate or polymer further comprises hopping among the plurality of predetermined discontinuous microwave energy bandwidths in a predetermined order and predetermined duration. In some embodiments, contacting the substrate or polymer with the plurality of predetermined discontinuous microwave energy frequencies to cure the substrate or polymer further comprises hopping among the plurality of predetermined discontinuous microwave energy frequencies in a predetermined order and predetermined duration. In some embodiments, at least one material property of the substrate or polymer is tuned by adjusting one or more tuning knobs configured to adjust at least one of frequency, power, temperature, pressure, waveguide configuration, chamber configuration, or in-chamber microwave distribution. In some embodiments, the plurality of predetermined discontinuous microwave energy bandwidths or the plurality of predetermined discontinuous microwave energy frequencies are provided at microwave frequencies ranging from 300 GHz to 300 MHz. In some embodiments, contacting the substrate or polymer with the plurality of predetermined discontinuous microwave energy bandwidths or the plurality of predetermined discontinuous microwave energy frequencies to cure the substrate or polymer is performed at about 100 degrees to about 500 degrees Celsius. In some embodiments, the plurality of predetermined discontinuous microwave energy bandwidths or the plurality of predetermined discontinuous microwave energy frequencies is provided at a sweep rate of about 25.0 microseconds per frequency to 1000 microseconds per frequency. In some embodiments, contacting a substrate or polymer comprises delivering microwave energy to the substrate or polymer within a microwave processing chamber under vacuum. In some embodiments, the substrate or polymer is one of an organic dielectric material formed from one of polyimide (PI), poly(p-phenylene benzobisoxazole (PBO), phenolic resin, epoxy, or benzocyclobutene (BCB), or an inorganic dielectric material formed of one of oxide, oxynitride, nitride, or carbide. In some embodiments, the polymer is polyimide (PI), poly(p-phenylene benzobisoxazole (PBO), phenolic resin, epoxy, or benzocyclobutene (BCB).

In some embodiments, the present disclosure relates to a substrate processing system, including: a variable frequency microwave chamber configured for contacting a polymer with a plurality of predetermined discontinuous microwave energy bandwidths or discontinuous microwave frequencies to cure the polymer. In some embodiments, the substrate processing system, further includes a vacuum substrate transfer chamber, wherein the variable frequency microwave chamber is coupled to the vacuum substrate transfer chamber; and an additional chamber coupled to the vacuum substrate transfer chamber, wherein the substrate processing system is configured to move the polymer from the variable frequency microwave chamber to the additional chamber under vacuum.

In some embodiments, the present disclosure relates to a computer readable medium, having instructions stored thereon which, when executed, cause a variable frequency microwave process chamber to perform a method, the method including: contacting a substrate or polymer with a plurality of predetermined discontinuous microwave energy bandwidths or a plurality of predetermined discontinuous microwave energy frequencies to cure the substrate or polymer.

While the foregoing is directed to embodiments of the present disclosure, other and further embodiments of the disclosure may be devised without departing from the basic scope thereof.

1. A method of curing a substrate or polymer using variable microwave frequency, comprising:
contacting a substrate or polymer with a plurality of predetermined discontinuous microwave energy bandwidths or a plurality of predetermined discontinuous microwave energy frequencies to cure the substrate or polymer.

2. The method of claim 1, wherein the substrate or polymer is cured at a temperature below 200 degrees Celsius.

3. The method of claim 1, wherein the substrate or polymer is cured in 1 to 180 minutes.

4. The method of claim 1, wherein the plurality of predetermined discontinuous microwave energy bandwidths comprises 2 to 20 predetermined discontinuous microwave energy bandwidths, or wherein the plurality of predetermined discontinuous microwave energy frequencies comprises 2 to 20 predetermined discontinuous microwave energy frequencies.

5. The method of claim 1, wherein contacting the substrate or polymer with the plurality of predetermined discontinuous microwave energy bandwidths to cure the substrate or polymer further comprises hopping among the plurality of predetermined discontinuous microwave energy bandwidths in a predetermined order.

6. The method of claim 1, wherein contacting the substrate or polymer with the plurality of predetermined discontinuous microwave energy frequencies to cure the substrate or polymer further comprises hopping among the plurality of predetermined discontinuous microwave energy frequencies in a predetermined order.

7. The method of claim 1, wherein contacting the substrate or polymer with the plurality of predetermined discontinuous microwave energy bandwidths to cure the substrate or polymer further comprises hopping among the plurality of predetermined discontinuous microwave energy bandwidths in a predetermined order and predetermined duration.

8. The method of claim 1, wherein contacting the substrate or polymer with the plurality of predetermined discontinuous microwave energy frequencies to cure the substrate or polymer further comprises hopping among the plurality of predetermined discontinuous microwave energy frequencies in a predetermined order and predetermined duration.

9. The method of claim 1, wherein at least one material property of the substrate or polymer is tuned by adjusting one or more tuning knobs configured to adjust at least one of frequency, power, temperature, pressure, waveguide configuration, chamber configuration, or in-chamber microwave distribution.

10. The method of claim 1, wherein the plurality of predetermined discontinuous microwave energy bandwidths or the plurality of predetermined discontinuous microwave energy frequencies are provided at microwave frequencies ranging from 300 GHz to 300 MHz.

11. The method of claim 1, wherein contacting the substrate or polymer with the plurality of predetermined discontinuous microwave energy bandwidths or the plurality of predetermined discontinuous microwave energy frequencies to cure the substrate or polymer is performed at about 100 degrees to about 500 degrees Celsius.

12. The method of claim 1, wherein the plurality of predetermined discontinuous microwave energy bandwidths or the plurality of predetermined discontinuous microwave energy frequencies is provided at a sweep rate of about 25.0 microseconds per frequency to 1000 microseconds per frequency.

13. The method of claim 1, wherein contacting a substrate or polymer comprises delivering microwave energy to the substrate or polymer within a microwave processing chamber under vacuum.

14. The method of claim 1, wherein the substrate or polymer is one of an organic dielectric material formed from one of polyimide (PI), poly(p-phenylene benzobisoxazole (PBO), phenolic resin, epoxy, or benzocyclobutene (BCB), or an inorganic dielectric material formed of one of oxide, oxynitride, nitride, or carbide.

15. The method of claim 1, wherein the polymer is polyimide (PI), poly(p-phenylene benzobisoxazole (PBO), phenolic resin, epoxy, or benzocyclobutene (BCB).

16. The method of claim 1, further comprising determining a plurality of discontinuous microwave energy bandwidths or a plurality of predetermined discontinuous microwave energy frequencies to cure the substrate or polymer.

17. The method of claim 16, further comprising selecting a plurality of discontinuous microwave energy bandwidths or a plurality of predetermined discontinuous microwave energy frequencies.

18. A substrate processing system, comprising:
a variable frequency microwave chamber configured for contacting a polymer disposed within the chamber during use with a plurality of predetermined discontinuous microwave energy bandwidths or discontinuous microwave frequencies to cure the polymer.

19. The substrate processing system of claim 18, further comprising:
a vacuum substrate transfer chamber, wherein the variable frequency microwave chamber is coupled to the vacuum substrate transfer chamber; and
an additional chamber coupled to the vacuum substrate transfer chamber, wherein the substrate processing system is configured to move the polymer from the variable frequency microwave chamber to the additional chamber under vacuum.

20. A computer readable medium, having instructions stored thereon which, when executed, cause a variable frequency microwave process chamber to perform a method, the method comprising:
contacting a substrate or polymer with a plurality of predetermined discontinuous microwave energy bandwidths or a plurality of predetermined discontinuous microwave energy frequencies to cure the substrate or polymer.
